(19) United States
(12) Patent Application Publication
(10) Pub. No.: US 2025/0166994 A1
(43) Pub. Date: May 22, 2025

(54) DEPOSITION PROCESS FOR PATTERNING EDGE PLACEMENT ERROR IMPROVEMENT

(71) Applicant: Applied Materials, Inc., Santa Clara, CA (US)

(72) Inventors: Zhiyu HUANG, Santa Clara, CA (US); Tong LIU, San Jose, CA (US); Madhur Singh SACHAN, Belmont, CA (US); Sony VARGHESE, Manchester, MA (US); Keiichi NAKAZAWA, Santa Clara, CA (US)

(21) Appl. No.: 18/601,809

(22) Filed: Mar. 11, 2024

Related U.S. Application Data
(60) Provisional application No. 63/626,883, filed on Jan. 30, 2024.
(60) Provisional application No. 63/600,571, filed on Nov. 17, 2023.

(51) Int. Cl. H01L 21/033; G03F 7/00; H01L 21/311; H01L 21/768

(52) U.S. Cl. CPC H01L 21/0337; G03F 7/70033; H01L 21/31116; H01L 21/76816

(57) ABSTRACT

A method of forming a pattern in a device structure formed on a substrate includes forming one or more patterning layers over a surface of a device structure formed on the substrate, forming patterning features in the one or more patterning layers, depositing a film layer over a surface of the one or more patterning layers and the patterning features, and etching at least a portion of a first device feature of a plurality of device features that is exposed within each of film layer openings formed within the patterning features.

### CROSS-REFERENCE TO RELATED APPLICATIONS

This application claims priority to U.S. Provisional Applications Ser. No. 63/600,571, filed Nov. 17, 2023, and Ser. No. 63/626,883, filed Jan. 30, 2024, each of which is herein incorporated by reference in its entirety.

### BACKGROUND

### Field

Embodiments of the invention generally relate to a process of patterning device layers used in semiconductor devices.

### Description of the Related Art

In the manufacture of integrated circuits (IC), shallow-trench-isolation (STI), metal interconnects, and related structures are used to form portions of IC devices, such as transistors, inductors, and diodes, that are formed on the surface of a semiconductor substrate. In some back end of the line (BEOL) processes, a dielectric layer is deposited and patterned to form a trench that defines the metal interconnect. One or more metal layers may then be deposited within the trench, and a chemical mechanical polishing (CMP) process may follow to planarize the deposited metal layers. The CMP process also removes excess metal from outside the boundaries of the trench, yielding a metal interconnect confined within the trench of the dielectric layer.

In some front end of the line (FEOL) and BEOL applications, the formed shallow-trench-isolation (STI) and metal interconnect structure are used to form at least a portion of a memory and logic device, such as a DRAM device. Current dynamic random access memory (DRAM) processes include the use of active-cut patterning (D1x, D1y node), cross self-aligned double patterning (X-SADP) or lithography-etch-lithography-etch (LELE) schemes. However, integration of these schemes causes shallow trench isolation (STI) active island area to be reduced as the technology node advances. As integrated circuit dimensions continue to decrease, there is a limit to how far these trenches can be scaled down based on the resolution limitations of the ultraviolet (UV), deep ultraviolet (DUV), and extreme-ultraviolet (EUV) radiation. More specifically, at 22 nanometer (nm) and smaller nodes, current lithography technologies cannot achieve the required dimensions. In one example, conventional EUV scanners are equipped with 0.33 numerical aperture (NA) optics, delivering about a 20 nm resolution. Such a resolution is suitable to print chips on manufacturing technologies featuring metal pitches between 30 nm and 38 nm. However, in a number of applications today, the critical dimensions (CDs) of the patterned features are required to be below 10 nm, and the state-of-the-art solutions to achieve the desired CD level create issues such as having a high complexity, reaching single exposure limits, reached the DUV self-aligned quadruple patterning (SAQP) limit, long processing times and high costs.

In most patterning processes, an offset error exists between the position of the imaged photolithographic pattern in a patterning layer and the position of the underlying structure that is to be patterned, due to pattern alignment errors inherent in the photolithographic pattern alignment process. As the device features become smaller and the spacing between the formed underlying features is reduced the effects of a placement error on the process of forming a semiconductor device have become a more significant. In one example, due to an offset error, patterned openings formed in the patterning layer(s) (e.g., photoresist and/or hard mask layer) can overlap with portions of adjacent structures that will then be subsequently etched in subsequent etching processes due to their exposure within each of the formed patterned openings. The undesired portions of the underlying features, which are etched in the subsequent etching processes, are often referred to as “mouse bite” damage which will adversely affect the performance or function of the underlying structure from which the material was undesirably removed.

Therefore, a process is needed to fabricate features at these sub-resolution dimensions. Moreover, there is also a need for an improved patterning process that will be able to avoid the “mouse bite” type damage to underlying structures and account for and/or minimize the effect of the inherent offset error created during a patterning process. There is also a need for a solution which reduces cost, processing time, and process variability due to the reduction in patterning steps.

### SUMMARY

Embodiments of the disclosure include a method of forming a pattern in a device structure formed on a substrate, comprising: forming one or more patterning layers over a surface of a device structure formed on the substrate, wherein the device structure comprises a plurality of device features having a first lateral dimension in a first direction, the plurality of device features is spaced apart in the first direction by a first distance, and the first direction is parallel to the surface of the device structure; forming patterning features in the one or more patterning layers, wherein each of the patterning features comprises a feature opening that comprises a first critical dimension (CD), and a first portion of a first device feature and a second portion of a second device feature of the plurality of device features are exposed within an opening in the one or more patterning layers that is defined by one or more surfaces of the feature opening; depositing a film layer over a surface of the one or more patterning layers and the patterning features, wherein the film layer formed within each of the feature openings comprises a portion of the film layer that is formed over the one or more surfaces of the feature opening and has a thickness that is measured in the first direction, one or more surfaces of the film layer exposed within each of the features openings define a film layer opening that is smaller than the first critical dimension (CD) of the feature opening, the film layer opening is disposed over at least a portion of the first portion of the first device feature, and the second portion of the second device feature of the plurality of device features is not exposed within the film layer opening; and etching the at least the first portion of the first device feature of the plurality of device features that is exposed within each of the film layer openings formed within the patterning features.

Embodiments of the disclosure include a method of forming a pattern in a device structure formed on a substrate, comprising: forming one or more patterning layers over a surface of a device structure formed on the substrate, wherein the device structure comprises a plurality of device features having a first lateral dimension in a first direction, the plurality of device features is spaced apart in the first direction by a first distance, and the first direction is parallel to the surface of the device structure; forming patterning features in the one or more patterning layers, wherein each of the patterning features comprises a feature opening that comprises a first critical dimension (CD), and a first portion of a first device feature and a second portion of a second device feature of the plurality of device features are exposed within an opening in the one or more patterning layers that is defined by one or more surfaces of the feature opening; directionally depositing a film layer on a surface of the one or more patterning layers and the patterning features, wherein the film layer formed within each of the feature openings comprises a first thickness and a second thickness that is formed over the one or more surfaces of the feature opening, wherein the first thickness is larger than a second thickness, the first thickness being measured in the first direction and the second thickness being measured in a second direction that is at an angle to the first direction and is parallel to the surface of the device structure, one or more surfaces of the film layer exposed within each of the features openings define a film layer opening that is smaller than the first critical dimension (CD) of the feature opening, the film layer opening is disposed over at least a portion of the first portion of the first device feature, and the second portion of the second device feature of the plurality of device features is not exposed within the film layer opening; and etching the at least the first portion of the first device feature of the plurality of device features that is exposed within each of the film layer openings.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings.

FIG. 1 is a flowchart illustrating a process of forming a patterned device structure, according to one or more embodiments described herein.

FIGS. 2A, 2B, and 2C include cross-sectional views of a partially formed device structure.

FIGS. 3A, 3B, 3C, 3D, 3E, 3F, 3G, 3H, 3I, 3J, 3K, 3L, 3M, 3N, 30, 3P, 3Q, 3R, 3S, 3T, and 3U include cross-sectional views following a series of operations illustrated in FIG. 1 that are used to form of a patterned device structure, according to one or more embodiments.

FIGS. 4A, 4B, 4C, 4D, 4E, 4F, 4G, 4H, 4I, 4J, 4K, and 4L include cross-sectional views following one or more operations illustrated in FIG. 1 that are used to form of a patterned device structure, according to one or more embodiments.

FIGS. 5A and 5B include cross-sectional views of a partially formed device structure following a portion of the series of operations illustrated in FIG. 1.

FIG. 5C is a side view of a directional deposition assembly according to embodiments of the disclosure.

To facilitate understanding, identical reference numerals have been used, where possible, to designate identical elements that are common to the Figures. It is contemplated that elements and features of one embodiment may be beneficially incorporated in other embodiments without further recitation.

### DETAILED DESCRIPTION

Embodiments of the disclosure include processes that are adapted to eliminate or minimize the effect of an offset error that typically exists between the position of the imaged photolithographic pattern in a patterning layer and the position of the underlying structure that is to be patterned due to pattern alignment errors inherent in the photolithographic pattern alignment process. Embodiments of the disclosure may also provide a patterning process sequence that can be used for patterning features having critical dimensions (CDs) below the direct printing capability of a lithographic process. In some applications, the methods disclosed herein can be used to improve the shallow trench isolation patterning using extreme ultraviolet (EUV) lithography and reverse self-aligned double patterning.

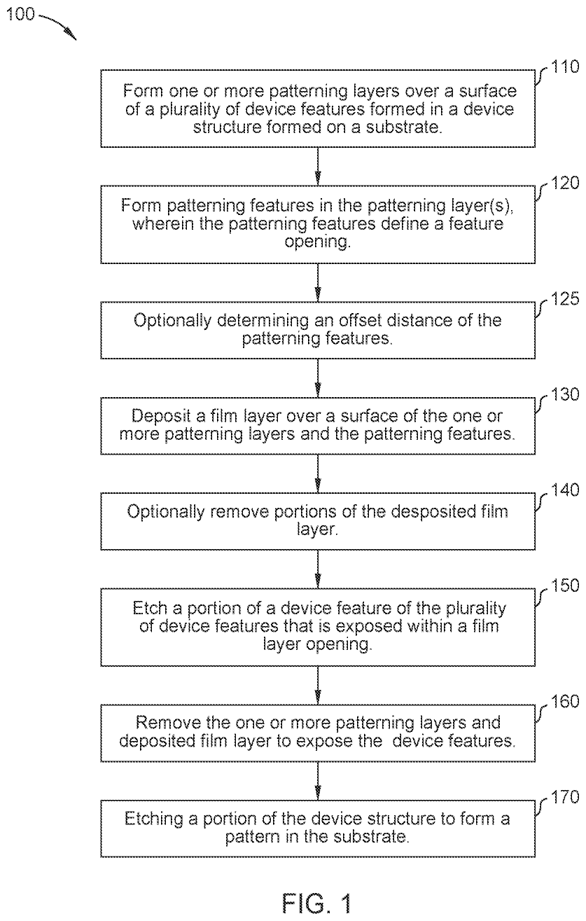

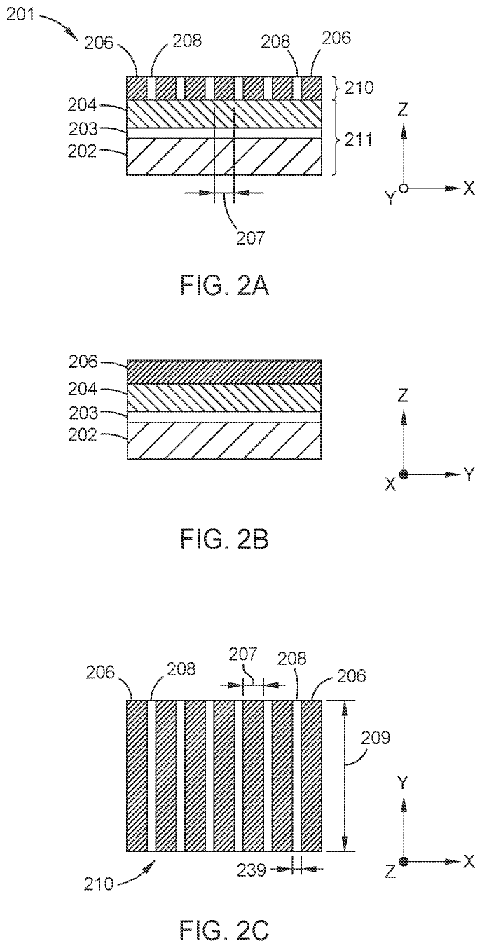

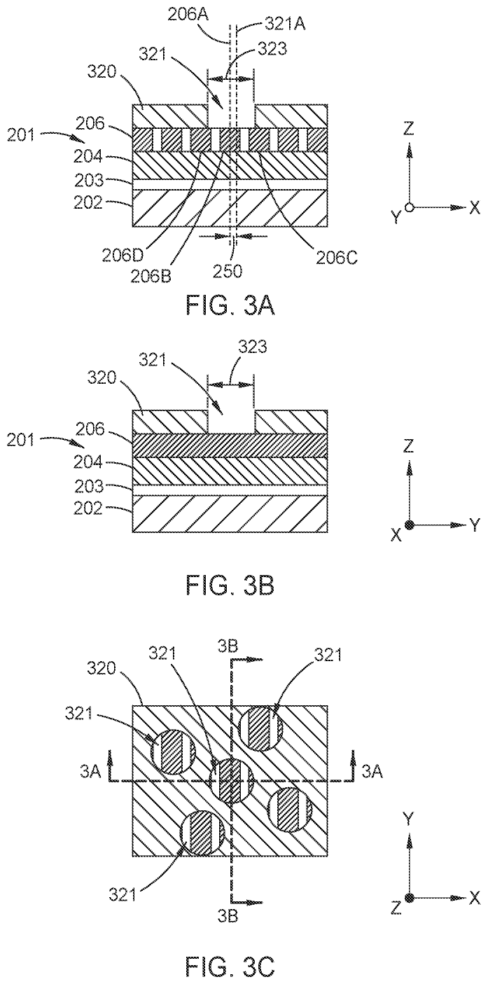

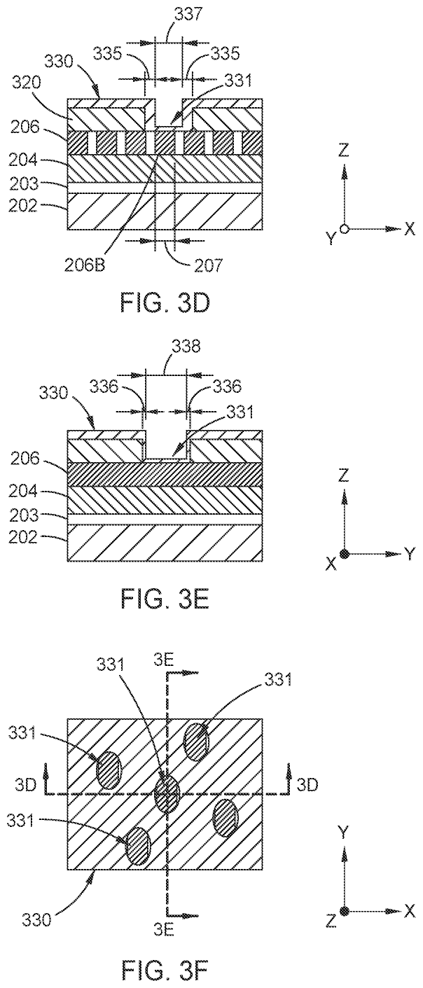

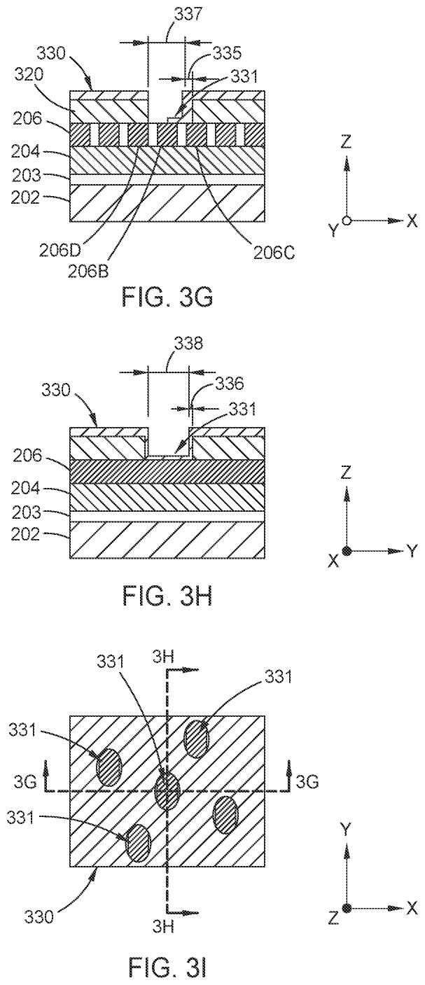

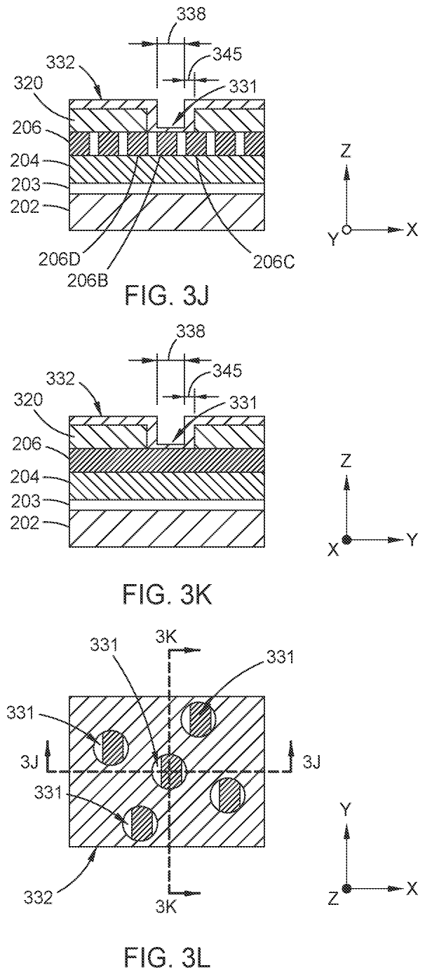

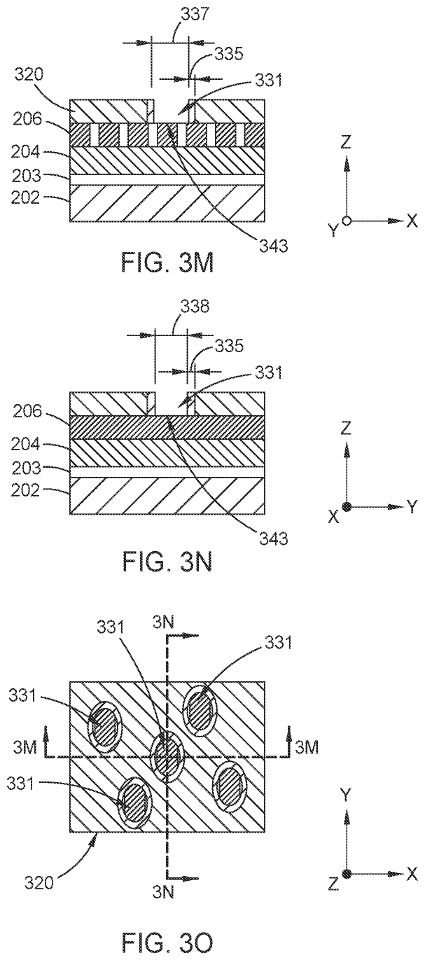

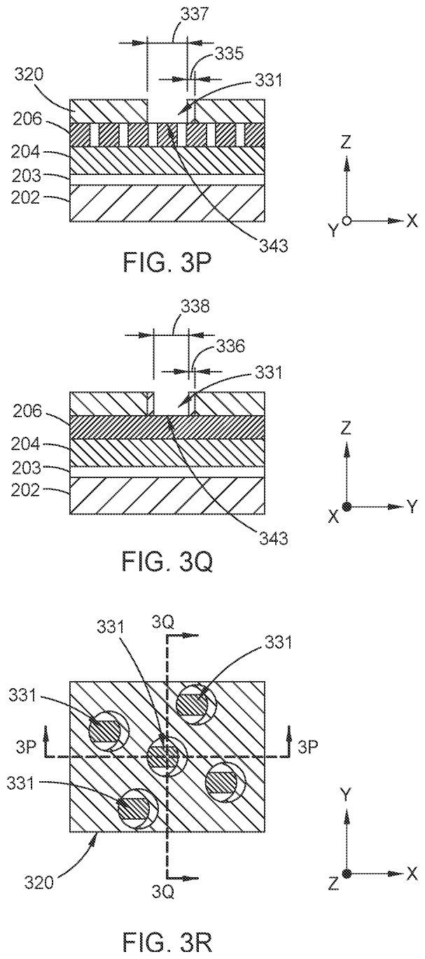

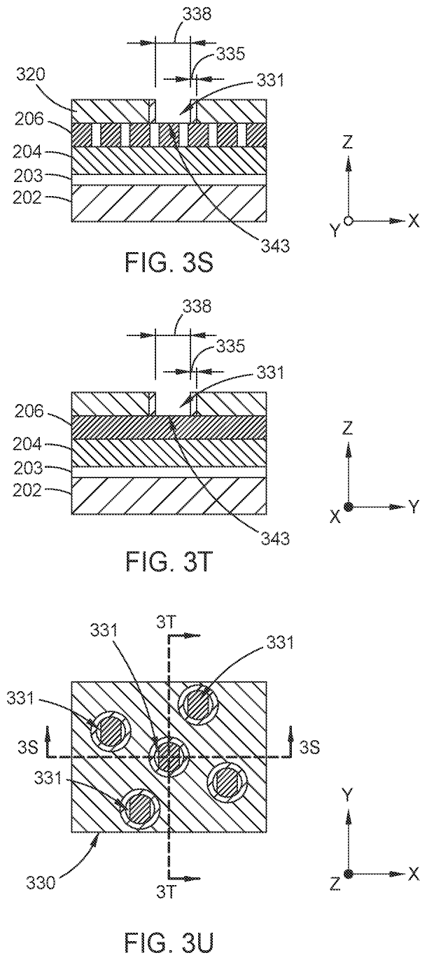

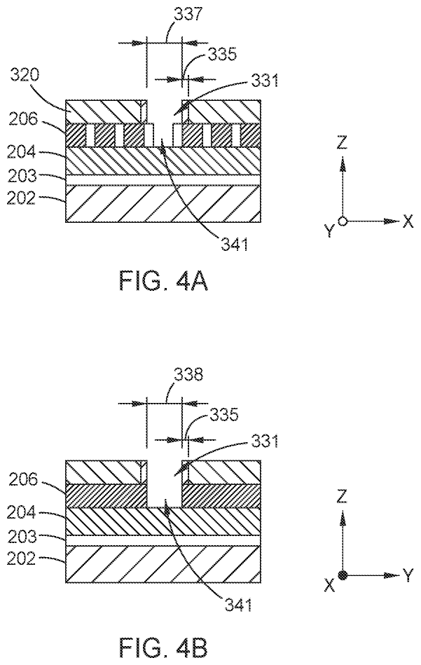

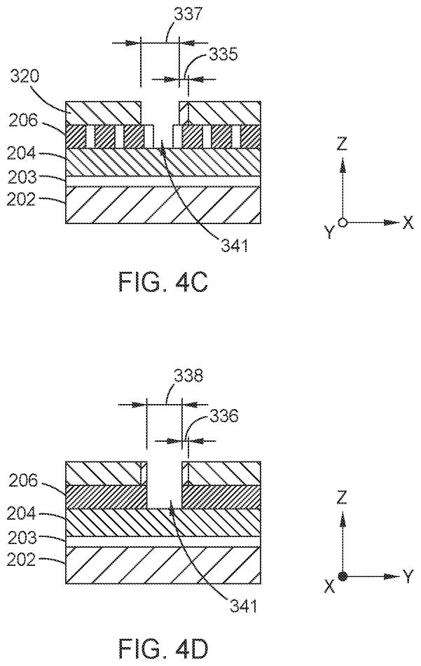

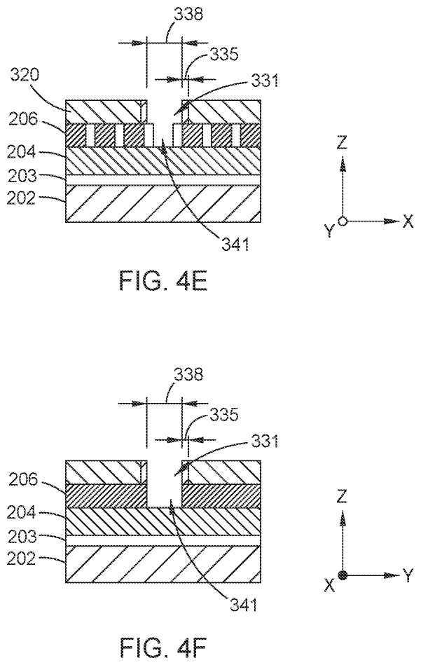

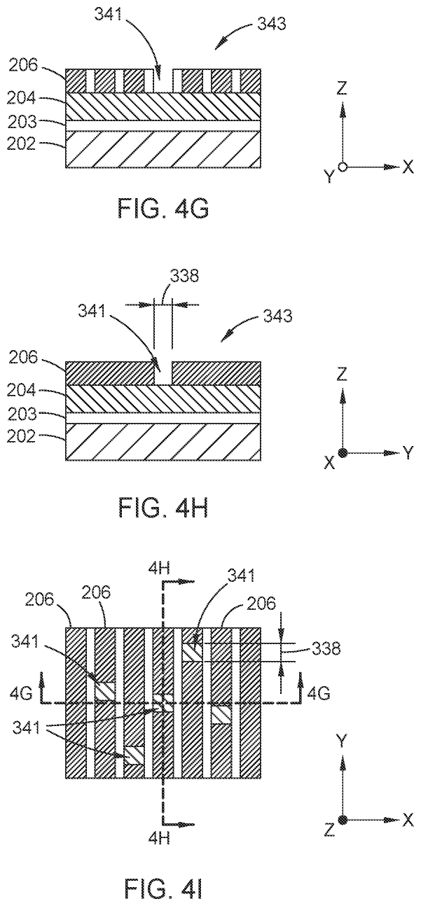

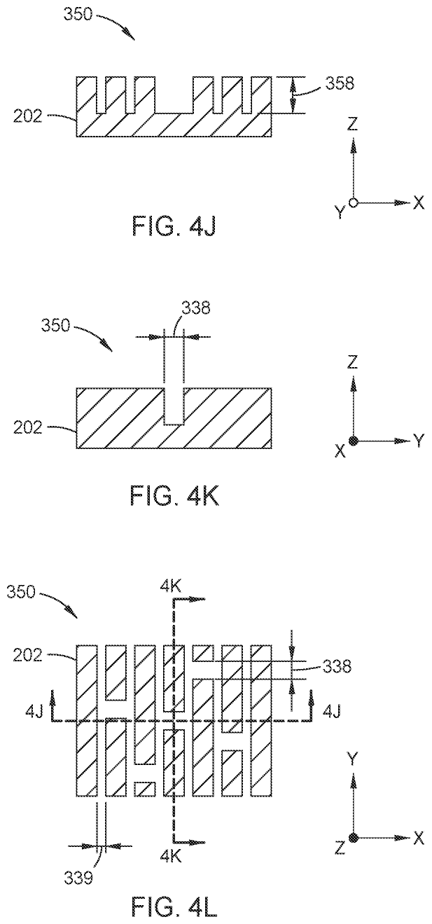

FIG. 1 is a flowchart illustrating a method 100 that is used to pattern a portion of a semiconductor device structure according to one or more embodiments of the disclosure provided herein. FIGS. 2A-2C illustrate cross-sectional views of a partially formed device structure that is used herein to help describe various embodiments of the disclosure provided herein. FIGS. 3A-3U include cross-sectional views following a series of operations illustrated in FIG. 1. FIGS. 4A-4L include cross-sectional views following one or more operations performed after performing one or more of the operations illustrated in FIG. 1 and FIGS. 3A-3U. The processes described herein are believed to be useful for the formation both logic and memory devices, which can include, but are not limited to, the formation of dynamic random access memory (DRAM) devices (e.g., 6F² DRAM), 3D memory devices (e.g., 3D NAND), backside power delivery network (BSPDN) containing devices, and complementary field-effect transistor (CFET) containing devices. Semiconductor processing systems that contain processing chambers, such as wet and dry processing chambers, can be used to perform the processing steps described herein.

Referring to FIGS. 2A-2C, the method 100 starts with an at least partially formed semiconductor device structure 201 that includes a device patterning layer 210 that is formed over a substrate 211. FIGS. 2A and 2B include side cross-sectional views of the partially formed semiconductor device structure 201, and FIG. 2C is a plan view of the partially formed semiconductor device structure 201. The partially formed semiconductor device structure 201 can be formed by use of various process integration schemes, such as a double patterning lithography (DPL), self-aligned quadruple patterning (SAQP), self-aligned double pattern (SADP), Litho-Etch-Litho-Etch (LELE), or other useful integration process. In one example, as shown in FIGS. 2A-2B, the device patterning layer 210 includes a plurality of device features 206 that are separated by an interlayer dielectric (ILD) 208. In some embodiments, the device features 206 include a metal or a semiconductor material, such as a silicon (Si) containing material (e.g., polysilicon, amorphous silicon, etc.), copper (Cu), molybdenum (Mo), tungsten (W), ruthenium (Ru) or other useful material. In one example, the substrate 211 can include a base substrate 202 that optionally includes one or more layers (e.g., dielectric layers) that are formed thereon. In some embodiments, the substrate 211 includes the base substrate 202, which includes a 100 mm, 150 mm, 200 mm, 300 mm or even a 450 mm crystalline silicon (Si) substrate, and a first layer 203 (e.g., silicon oxide (SiOx)) and a second layer 204 (e.g., silicon nitride (SiNx) layer). The ILD 208 can include a dielectric material such as silicon oxide (SiOx) containing material, a low-k dielectric or other useful material that can be used to provide etch selectivity relative to the device features 206.

In some memory and logic structures, as shown in FIG. 2C, a spacing 239 is formed between the device features 206 that has a critical dimension (CD) that is less than about 10 nanometers (nm) and a first lateral dimension 207 of the device features 206 are greater than or equal to 10 nm, such as, for example, between about 10 nm and 15 nm, such as 12 nm. In other words, in some embodiments, the semiconductor device structure 201 includes a plurality of device features 206 having a first lateral dimension 207, as measured in a first direction (e.g., X-direction), and the plurality of device features 206 are spaced apart in the first direction by a first distance, or gap, that is filled with the ILD 208. As noted above, conventional EUV scanners are commonly equipped with 0.33 numerical aperture (NA) optics that will deliver a 20 nm resolution that is suitable for forming structures that have pitches between 30 nm and 38 nm. However, some device fabrication applications seek to subsequently separate portions of each of the device features 206, such as forming a “tip-to-tip” Y-direction opening dimension 338 (FIGS. 4A-4L) in the device features 206, that have a desired critical dimension that is less than the resolution of a single exposure patterning process. In some embodiments, the Y-direction opening dimension 338 is configured to segment a device feature 206, which has a second lateral dimension 209 (FIG. 2C) that is greater than the first lateral dimension 207. The desire to form patterned features that have a critical dimension less than the resolution of a single exposure patterning process has required device manufacturers to use much more complex patterning processes to form these smaller features. In some examples, such as in DRAM applications, the desired Y-direction opening dimension 338 is less than 10 nm.

At operation 110, as illustrated in FIGS. 1 and 3A-3C, a patterning layer 320 is formed on a surface of the partially formed semiconductor device structure 201. FIGS. 3A and 3B include two orthogonally oriented side cross-sectional views of the partially formed semiconductor device structure 201, and FIG. 3C is a plan view of the partially formed semiconductor device structure 201. FIGS. 3A and 3B are formed by use of the sectioning lines 3A-3A and 3B-3B shown in FIG. 3C, respectively. In one embodiment, the patterning layer 320 includes a plurality of layers, such as a carbon hard mask layer (not shown) positioned over the surface of the device patterning layer 210, a dielectric anti-reflective coating (DARC) layer (not shown) positioned over the surface of the carbon hard mask layer, a photoresist (PR) under layer (not shown) positioned over the surface of the DARC layer, and a photoresist layer (not shown) positioned over the surface of the PR under-layer. In some embodiments, the patterning layer 320 includes a EUV photoresist. In some embodiments, the patterning layer 320 includes a carbon containing layer such as a carbon containing hardmask layer (e.g., amorphous carbon layer).

During operation 120, as illustrated in FIGS. 3A-3C, a plurality of patterned openings 321 are formed in a plurality of regions in the patterning layer 320, such as the five regions illustrated in FIG. 3C, by use of various conventional direct photolithography techniques. As illustrated in FIGS. 3A and 3B, each of the patterned openings 321 include a lateral dimension 323 that has a critical dimension (CD) that is greater than or equal to the limit of a direct print lithographic process. In one example, an EUV scanner is equipped with 0.33 numerical aperture (NA) optics that are configured to form the patterned openings 321 such that they have a lateral dimension 323 that is 20 nm in size by exposing the patterning layer 320 to EUV radiation and then developing the exposed patterning layer 320. In some embodiments, the patterned openings 321 have a circular, square, rectangular, oval or other desired opening shape. While not intending to be limiting to the various aspects of the disclosure provided herein, and for simplicity of discussion reasons, circular shaped patterned openings 321 are primarily disclosed herein. The term “patterned opening” 321 is also referred to herein as a “feature opening.” In some embodiments, each patterned opening 321 includes a first critical dimension (CD) that is greater than at least one dimension of an underlying feature within the semiconductor device structure 201, such as the first lateral dimension 207 of the device features 206.

As shown in FIG. 3A, the position of the imaged photolithographic pattern used to form the patterned openings 321 in the patterning layer 320 and the position of the underlying plurality of device features 206 and ILD 208 includes an offset error 250 that is formed in one or more lateral directions. The offset error 250 can be characterized by an offset distance that is measured from the center of a device feature 206 that is to be etched in a subsequent etching process and the center of the patterned opening 321 positioned thereover. In one example, the offset error 250 is measured from the center line 206A of the device feature 206 to the center line 321A of the patterned opening 321 due to the offset error being aligned a first direction, such as the X-direction in this example.

As shown in FIGS. 3A and 3C, the lateral dimension 323 of the patterned openings 321 is purposely made larger than an opening that is desired to be formed in the underlying device features 206, such as forming an opening in an underlying layer using an “active cut” patterning step. In one example, as will be discussed further below, the lateral dimension 323, which is measured from the sidewalls of each of the circular shaped patterned opening 321, is about 20 nm in size while it is desired to form a “cut” in the exposed region of a device feature 206 that is about 10 nm or less. However, in one example, as illustrated in FIGS. 3A and 3C the lateral dimension 323 of the patterned opening 321 includes portions of adjacent device features 2060-206D due to the selected lateral dimension 323 of the patterned opening 321 and the relatively fine pitch of the underlying features formed in the semiconductor device structure 201. In this example, due to the offset error 250 each of the patterned openings 321 expose a larger portion of the adjacent device feature 206C formed on the right side of the device feature 206B than the adjacent device feature 206D formed on the left side of the device feature 206B. As noted above, if an etching process were performed using the formed patterned opening 321 directly after performing operation 120 the exposed portions of the adjacent device features 206C and 206D would be undesirably removed during the etching step used to remove the desired portion of the device features 206B.

At operation 125, an optional device pattern inspection process can be performed on the semiconductor device structure 201 to determine the offset error 250 of a plurality of patterned openings 321 formed thereon. In some embodiments, the offset error 250 can be determined by use of a conventional optical inspection technique, scanning electron microscope (SEM), or other useful automated or non-automated inspection technic performed after the patterning process(es) have been performed during operation 120. Information regarding the offset error 250 determined at one or more of the patterned openings 321 can be stored within a memory and used by a controller (not shown) that is able to communicate with and/or control at least one aspect of a subsequent non-conformal deposition layer 330 or conformal deposition layer 332 deposition process so that a desired film layer opening 331 size and/or shape can be formed within the patterned openings 321.

In some embodiments, the controller will generally include a programmable central processing unit (CPU) (not shown) which is operable with a memory (not shown) and support circuits (not shown) that are configured to receive input regarding the detected offset error 250 from sensors or input from a user and provide commands that are used to control one or more aspects of the subsequent operations. The support circuits of the controller are conventionally coupled to the CPU and will typically include cache, clock circuits, input/output subsystems, power supplies, and the like, and combinations thereof coupled to the various components of the deposition system, to facilitate control thereof. The CPU is one of any form of general purpose computer processor used in an industrial setting, such as a programmable logic controller (PLC), for controlling various components and sub-processors of the deposition system. The memory, coupled to the CPU, is non-transitory (e.g., non-volatile memory) and is typically one or more of readily available memories such as random access memory (RAM), read only memory (ROM), floppy disk drive, hard disk, or any other form of digital storage, local or remote. Typically, the memory is in the form of a non-transitory computer-readable storage media containing instructions (e.g., non-volatile memory), which when executed by the CPU, facilitates the operation of the deposition system. The instructions in the memory are in the form of a program product such as a program that implements the methods of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

At operation 130, as illustrated in FIGS. 3D-3F and 3G-3I, a non-conformal deposition layer (also referred to as a “film layer”) 330 is formed over the surface of the patterning layer 320 and surfaces of the patterned openings 321, which includes the sidewalls of the patterning layer 320. In some cases, the non-conformal deposition layer 330 is also disposed over at least a portion of the exposed semiconductor device structure 201, such as a portion of a device feature 206 and the ILD 208. FIGS. 3D-3F and FIGS. 3G-3I illustrate a non-conformal deposition layer 330 formed over the surface of the patterning layer 320 by use of two different types of directional deposition processes.

FIGS. 3D and 3E include two orthogonally oriented side cross-sectional views of the partially formed semiconductor device structure 201, and FIG. 3F is a plan view of the partially formed semiconductor device structure 201. FIGS. 3D and 3E are formed by use of the sectioning lines 3D-3D and 3E-3E shown in FIG. 3F, respectively. Similarly, FIGS. 3G and 3H include two orthogonally oriented side cross-sectional views of the partially formed semiconductor device structure 201, and FIG. 3I is a plan view of the partially formed semiconductor device structure 201. FIGS. 3G and 3H are formed by use of the sectioning lines 3G-3G and 3H-3H shown in FIG. 3I, respectively.

As illustrated in FIGS. 3D-3F, the non-conformal deposition layer 330 has an asymmetric lateral deposition thickness in at least two different lateral directions due to the use of a directional deposition process, which is further described below. In one example, due to the directional nature of the deposition process, the thickness 336 of the non-conformal deposition layer 330 formed on the sidewalls of the patterned openings 321 in the Y-direction is thinner than the thickness 335 of the non-conformal deposition layer 330 formed on the sidewalls in the X-direction. At the end of the deposition process performed during operation 130, the Y-direction opening dimension 338 is reduced to a desired CD dimension (e.g., 10 nm) while the X-direction opening dimension 337 is configured to cover the exposed portions of the adjacent device features 206C-206D. Due to the configuration of the deposited non-conformal deposition layer 330 the placement error of the patterned openings 321 in the first direction (X-direction) can be accounted for and the subsequent etching process(es) used to remove the portion of the device feature 206B can be assured to physically isolate the remaining portions of the device feature 206B from each other and not etch the adjacent device features 206C and 206D. The surface of the deposited non-conformal deposition layer 330 within each patterned opening 321 defines a film layer opening 331, which has non-equal opening dimensions (e.g., X-direction opening dimension 337 and Y-direction opening dimension 338), that is then used in one or more subsequent etching processes to define the CD of an etched portion of a material (e.g., portion of the device feature 206) exposed within the film layer opening 331. In this example, the formed thickness 336 of the non-conformal deposition layer 330 relative to the formed thickness 335 is known for a selected lateral dimension 323 of a patterned opening 321 so that a desired film layer opening 331 can be formed with a desired CD in at least one direction, such as the Y-direction opening dimension 338, can be created in the device feature 206B. In this example, the formed thicknesses 335, 336 of the non-conformal deposition layer 330 is selected by user input or by use of input received by the controller so that a desired CD of an opening can be created within the device feature 206B without harming the adjacent device features 206C-206D.

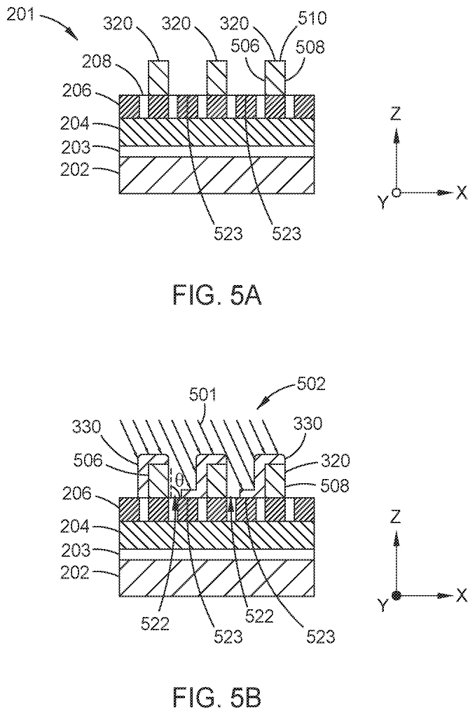

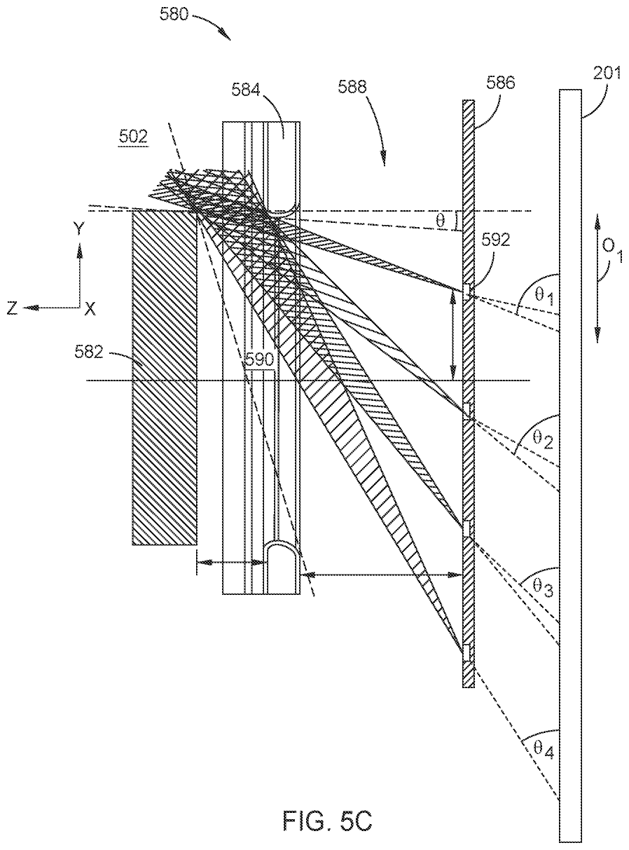

As will be discussed further below, the process of forming the non-conformal deposition layer 330 can require two or more extraction assemblies 580 (FIG. 5C) that are configured to directionally deposit the non-conformal deposition layer 330 in two opposing directions (e.g., +Y-direction and −Y-direction in FIG. 3F) to cause the formed thicknesses 335 to be greater than the formed thicknesses 336. In this case, the formed non-conformal deposition layer 330 will be referred to herein as a dual-direction asymmetric non-conformal deposition layer 330.

Alternately, as shown in FIGS. 3G-3I, a thickness 336 of the non-conformal deposition layer 330 on the sides of the patterned openings 321 is smaller than the formed thickness 335 of the non-conformal deposition layer 330 on an opposing side of the patterned openings 321. Operation 130 performed in this example can be especially useful in cases where the lateral dimension 323 of the patterned opening 321 and the offset error 250 are formed so that only a portion of one adjacent device feature, such as device feature 206C, is exposed within film layer opening 331. In this case, the asymmetric lateral deposition thickness in at least one lateral direction can be used to cover the exposed portion of the adjacent device feature and allow a desired CD to be formed in a desired alternate direction. In one example, due to the directional nature of the deposition process, the thickness 335 of the non-conformal deposition layer 330 formed on the sidewalls of the patterned openings 321 in the X-direction is configured to cover the exposed portion of the adjacent device feature 206C while forming a desired film layer opening 331 size in the opposing direction (e.g., Y-direction opening dimension 338). In this example, the formed thicknesses 335, 336 of the non-conformal deposition layer 330 is selected by user input or by input received by the controller so that a desired CD of an opening can be created within the device feature 206B without harming the adjacent device feature 206C.

In one example, a process and apparatus for forming the single direction asymmetric non-conformal deposition layer 330 is further described below in relation to FIGS. 5A-5C. In this case, the process of forming the non-conformal deposition layer 330 can require one or more extraction assemblies 580 that are configured to directionally deposit the non-conformal deposition layer 330 in a single direction (e.g., +Y-direction or −Y-direction in FIG. 3I) to cause the single sided formed thickness 335 to be greater than the formed thicknesses 336 formed in a second orthogonal direction. In this case, the surface of the deposited non-conformal deposition layer 330 and also a portion of the patterning layer 320, which does not include a portion of the non-conformal deposition layer 330 formed thereon, within each patterned opening 321 defines the film layer opening 331 that is then used in one or more subsequent etching processes to define the CD of an etched portion of a material exposed within the film layer opening 331.

While not intending to limit the scope of the disclosure provided herein, FIGS. 5A-5C illustrate aspects of a non-conformal deposition layer 330 deposition process and apparatus that can be used during operation 130 to form an asymmetric non-conformal deposition layer 330, such as the non-conformal deposition layer 330 illustrated in FIGS. 3G-3I. FIG. 5A depicts a side cross-sectional view of a plurality of patterned openings 321 formed in the patterning layer 320. As shown, each of the plurality of patterned openings 321 include a first sidewall 506, a second sidewall 508, and an upper surface 510 connecting the first sidewall 506 and the second sidewall 508. In some embodiments, the plurality of patterned openings 321 may be formed by a lithography and etch process (e.g., mask etch process), wherein the lithography process has a lower resolution than the desired final structure. Although non-limiting, the plurality of patterned openings 321 may be made from any known hardmask material, e.g., oxide, silicon, carbon, silicon nitride, and the like. In some embodiments, a patterning layer 320 may be formed over exposed surfaces of the patterning layer 320 and exposed portion of the semiconductor device structure 201, including over the first sidewall 506, the second sidewall 508, the upper surface 510 of the patterning layer 320, and over a top surface 523 of the exposed portion of the semiconductor device structure 201.

FIG. 5B depicts a side cross-sectional view of the portion of the semiconductor device structure 201 during formation of a non-conformal deposition layer 330 over the patterning layer 320 and exposed portion of the semiconductor device structure 201. In some embodiments, the non-conformal deposition layer 330 is formed by use of the directional deposition process. More specifically, the directional deposition process is used to deliver a masking material (e.g., oxide, carbon, nitride, silicon (Si), a self-assembled monolayer (SAM), etc.) at a non-zero angle of inclination ϕ relative to a perpendicular direction (e.g., Z-direction) to the top surface 523 of the semiconductor device structure 201. In some embodiments, the non-zero angle of inclination may be selected so that the masking material impacts just the first sidewall 506 and the upper surface 510 of each of the patterned openings 321. In some embodiments, the masking material generally does not form along the top surface 523 of the semiconductor device structure 201 in an area 522 directly adjacent the second sidewall 508 of each of the patterned openings 321. As further shown, the non-conformal deposition layer 330 is prevented from being formed along the second sidewall 508 of each of the patterned openings 321. It will be appreciated that coverage by the masking material is dependent on the non-zero angle of inclination ϕ.

FIG. 5C illustrates a side view of an apparatus for forming the non-conformal deposition layer 330 according to embodiments of the disclosure. As shown, an extraction assembly 580 may be coupled to the plasma chamber 502, and include an extraction plate 584 and a beam blocker 582. The extraction assembly 580 may further include a collimation plate 586, disposed between the extraction plate 584 and the non-conformal deposition layer 330 formed over the patterning layer 320 and exposed portion of the semiconductor device structure 201. Extraction of an ion beam may be achieved by a bias voltage applied between the plasma chamber 502 and non-conformal deposition layer 330, depending upon the targeted ion energy. To generate an angled ion beam, the beam blocker 582 may be arranged to block a portion of the aperture 590, formed with the extraction plate 584, so that an ion beam 588 is extracted from the plasma chamber 502 along the edge of the aperture as shown.

Notably, ions used to form the non-conformal deposition layer 330 may exit the plasma chamber 502 over a range of angles. To select for a given angle of incidence (or narrow range of angles of incidence) (K), the collimation plate 586 may be provided with a collimation aperture 592 arranged at a specific offset O with respect to an edge of the aperture 590. FIG. 5C illustrates four possible placements for the collimation aperture 592. Increasing the value of O will lead to a higher value of k. In FIG. 5C, for an offset O1, the corresponding q1 is 17-21 degrees. Larger offsets will produce larger angles of incidence. Thus, for a given placement of the collimation aperture 592, ions exiting the plasma chamber 502 will be blocked from traversing to the non-conformal deposition layer 330, except those ions having the suitable angle of incidence to pass through the collimation aperture 592 and strike the portions of the forming non-conformal deposition layer 330. Thus, by switching between different collimation plates having different value of O, the apparatus of FIG. 5C presents a convenient means to vary the angle of incidence of ions of a reactive beam to be applied to a substrate to change the coverage of the non-conformal deposition layer 330 on the patterned openings 321, as generally shown in FIG. 5B.

In an alternate version of operation 130, as illustrated in FIGS. 3J-3L, a conformal deposition layer 332 is alternately formed over the surface of the patterning layer 320 and surfaces of the patterned openings 321, which includes the sidewalls of the patterning layer 320. In some cases, the conformal deposition layer 332 is also disposed over at least a portion of the exposed semiconductor device structure 201, such as a portion of a device feature 206B and the ILD 208. FIGS. 3J-3L illustrate a conformal deposition layer 332 formed over the surface of the patterning layer 320 by use of a conformal deposition processes, such as a chemical vapor deposition (CVD) process, an atomic layer deposition (ALD), a plasma enhanced atomic layer deposition (PEALD), a plasma enhanced chemical vapor deposition (PECVD) process, or other useful deposition technique. FIGS. 3J and 3K include two orthogonally oriented side cross-sectional views of the partially formed semiconductor device structure 201, and FIG. 3L is a plan view of the partially formed semiconductor device structure 201. FIGS. 3J and 3K are formed by use of the sectioning lines 3J-3J and 3K-3K shown in FIG. 3L, respectively.

As illustrated in FIGS. 3J-3L, the conformal deposition layer 332 has a symmetric lateral deposition thickness due to the use of a conformal deposition process. In one example, due to the non-directional nature of the deposition process, the thickness 345 of the conformal deposition layer 332 formed on the sidewalls of the patterned openings 321 in the Y-direction is the same as the thickness 345 of the conformal deposition layer 332 formed on the sidewalls in the X-direction. At the end of the deposition process performed during this alternate version of operation 130, the Y-direction opening dimension 338 will have a desired CD dimension (e.g., 10 nm) while the similar X-direction opening dimension 338 is configured to cover the exposed portions of the adjacent device features 206C-206D such that the placement error of the patterned openings 321 in the first direction (X-direction) can be accounted for and the subsequent etching process(es) used to remove the portion of the device feature 206B can be assured to physically isolate the remaining portions of the device feature 206B from each other and not etch the adjacent device features 2060-206D. As shown in FIGS. 3J-3L, the thickness 345 of the conformal deposition layer 332 is selected to achieve a desired CD dimension while assuring that the exposed portions of the adjacent device features 206C-206D are covered. The surface of the deposited conformal deposition layer 332 within each patterned opening 321 defines the film layer opening 331 that is then used in one or more subsequent etching processes to define the CD of an etched portion of a material (e.g., portion of the device feature 206B) exposed within the film layer opening 331. In this example, the formed thickness 345 of the conformal deposition layer 332 is selected by user input or by input received by the controller so that a desired CD of an opening can be created within the device feature 206B without harming the adjacent device features 206C-206D.

At operation 140, as illustrated in FIGS. 3M-30, 3P-3R and 3S-3U, optionally a layer trimming process is performed to remove one or more portions of the deposited non-conformal deposition layer 330 or conformal deposition layer 332 to expose a portion of the top surface 343 of the device patterning layer 210 which is defined by the film layer opening 331. FIGS. 3M-30, and 3P-3R each illustrate the remaining portions of the non-conformal deposition layer 330 after performing the trimming process on a dual-direction asymmetric non-conformal deposition layer 330 and a single direction asymmetric non-conformal deposition layer 330, respectively. FIGS. 3S-3U illustrate the remaining portions of the conformal deposition layer 332 after performing the trimming process on the conformal deposition layer 332. In some embodiments, the layer trimming process can be performed in the extraction assembly 580, or in a separate plasma processing chamber, by use of plasma dry etching process that is configured to remove the portions of the non-conformal deposition layer 330 or conformal deposition layer 332 by use of a sputtering process. In some embodiments, the trimming process can include a reactive ion etching process that is configured to selectively etch the material (e.g., carbon) used to form the non-conformal deposition layer 330 or conformal deposition layer 332 relative to the materials found in the device features 206 and the ILD 208. As shown in FIGS. 3M-30, 3P-3R and 3S-3U, the trimming process can include the removal of the non-conformal deposition layer 330 or conformal deposition layer 332 from the top surface 343 of the device patterning layer 210 and also at least a portion of non-conformal deposition layer 330 or conformal deposition layer 332 formed on the top surface of the patterning layer 320. The optional trimming process can also be used to further adjust the X-direction opening dimension and/or the Y-direction opening dimension as desired by adjusting one or more plasma processing and/or chemical etching process parameters used to remove the portions of the non-conformal deposition layer 330 or conformal deposition layer 332.

At operation 150, as shown in FIGS. 4A-4B, 4C-4D and 4E-F, an etching process is performed on the exposed portion of the semiconductor device structure 201 to selectively remove portions the device features 206 that are exposed after performing operations 110-130 and optionally operation 140. FIGS. 4A and 4B include two orthogonally oriented side cross-sectional views of the partially formed semiconductor device structure 201 after performing operation 150 on the structures illustrated in FIGS. 3D-3E or FIGS. 3M-3N, depending on whether operation 140 is performed. FIGS. 4C and 4D include two orthogonally oriented side cross-sectional views of the partially formed semiconductor device structure 201 after performing operation 150 on the structures illustrated in FIGS. 3G-3H or FIGS. 3P-3Q, depending on whether operation 140 is performed. FIGS. 4E and 4F include two orthogonally oriented side cross-sectional views of the partially formed semiconductor device structure 201 after performing operation 150 of the structures illustrated in FIGS. 3J-3K or FIGS. 3S-3T, depending on whether operation 140 is performed. The etching process performed during operation 150 will include the use of an etchant that will selectively remove the material used to form the exposed device feature 206 versus the material used to form the ILD 208 and stop etching when a portion of the substrate 211 (e.g., second layer 204) is exposed within the opening 341 (FIGS. 4A-4F) during the etching process. In other words, the substrate 211 will act as an etch stop during the selective removal of the device feature material. In one example, the second layer 204 of the substrate is a silicon nitride (SiN) containing layer and the etchant used to remove the remaining portions of the device patterning layer 210 includes wet or dry etching chemistries that are configured to selectively etch exposed portion of the metal or silicon containing material of the device feature 206 versus the SiOₓ of the ILD 208 and the SiNₓ material of the second layer 204.

At operation 160, as shown in FIGS. 4G-4I, an etching process is performed to remove the remaining portions of the patterning layer 320 and non-conformal deposition layer 330 or conformal deposition layer 332 to expose the top surface 343 of the semiconductor device structure 201. FIGS. 4G and 4H include two orthogonally oriented side cross-sectional views of the partially formed semiconductor device structure 201, and FIG. 41 is a plan view of the partially formed semiconductor device structure 201. FIGS. 4G and 4H are formed by use of the sectioning lines 4G-4G and 4H-4H shown in FIG. 4I, respectively. The etching process performed in operation 160 will include the use of an etchant that will selectively remove the material used to form the patterning layer 320 and non-conformal deposition layer 330 or conformal deposition layer 332. In other words, the remaining materials found on the top surface 343 of the semiconductor device structure 201 act as an etch stop during the selective removal of the patterning layer 320 and non-conformal deposition layer 330 or conformal deposition layer 332. In one example of operation 160, wet and/or dry etching chemistries and processes are used to selectively remove the patterning layer 320 and non-conformal deposition layer 330 or conformal deposition layer 332.

At operation 170, as shown in FIGS. 4J-4L, a series of etching processes are performed to form a patterned substrate 350. FIGS. 4J and 4K include two orthogonally oriented side cross-sectional views of the partially formed semiconductor device structure 201, and FIG. 4L is a plan view of the patterned substrate 350. FIGS. 4J and 4K are formed by use of the sectioning lines 4J-4J and 4K-4K shown in FIG. 4L, respectively. The series of etching processes used to form the patterned substrate 350 include a first etching operation (not shown) that includes the selective removal of the ILD 208 by use of a wet or dry etching process to form openings between the remaining portions of the device features 206. The openings will include the channels formed between adjacent device features 206 and the openings 341 formed between adjacent portions of the device features 206 formed during operation 150.

Next, a second etching operation (not shown) is performed that includes the selective removal of the one or more portions of the substrate 211 that are exposed within the openings formed between the remaining portions of the device features 206, such as the channels formed between adjacent device features and the openings 341 formed between adjacent portions of the device features 206 formed during operation 150. The second etching operation can include the selective removal of the various portions of the substrate 211 versus the material used to form the device features 206 by use of a wet or dry etching process. In some embodiments, the etching process performed during the second etching operation is configured to etch a desired depth 358 within the base substrate 202.

A third etching operation (not shown) that includes the selective removal of the device features 206 and one or more portions of the substrate 211, such that only a portion of the substrate 211 remains, such as the remaining portions of the base substrate 202. The third etching operation can include the removal of the various portions of the device features 206 and substrate 211 by use of a chemical mechanical polishing (CMP) process and/or a wet and/or dry etching process.

The remaining portions of the base substrate 202 are thus used to form the patterned substrate 350. The patterned substrate 350 can then be used in the formation of one or more logic or memory devices.

While the foregoing is directed to embodiments of the present disclosure, other and further embodiments of the disclosure may be devised without departing from the basic scope thereof, and the scope thereof is determined by the claims that follow.

1. A method of forming a pattern in a device structure formed on a substrate, comprising:
forming one or more patterning layers over a surface of a device structure formed on the substrate, wherein:
the device structure comprises a plurality of device features having a first lateral dimension in a first direction,
the plurality of device features is spaced apart in the first direction by a first distance, and
the first direction is parallel to the surface of the device structure;
forming patterning features in the one or more patterning layers, wherein:
each of the patterning features comprises a feature opening that comprises a first critical dimension (CD), and
a first portion of a first device feature and a second portion of a second device feature of the plurality of device features are exposed within an opening in the one or more patterning layers that is defined by one or more surfaces of the feature opening;
depositing a film layer over a surface of the one or more patterning layers and the patterning features, wherein:
the film layer formed within each of the feature openings comprises a portion of the film layer that is formed over the one or more surfaces of the feature opening and has a thickness that is measured in the first direction,
one or more surfaces of the film layer exposed within each of the features openings define a film layer opening that is smaller than the first critical dimension (CD) of the feature opening,
the film layer opening is disposed over at least a portion of the first portion of the first device feature, and
the second portion of the second device feature of the plurality of device features is not exposed within the film layer opening; and
etching the at least the first portion of the first device feature of the plurality of device features that is exposed within each of the film layer openings formed within the patterning features.

2. The method of claim 1, wherein each of the plurality of device features have a second lateral dimension that is measured in a second direction that is orthogonal to the first direction, and the first critical dimension (CD) is less than the second lateral dimension.

3. The method of claim 1, wherein the film layer comprises carbon, silicon oxide, silicon nitride, silicon, or a self-assembled monolayer (SAM).

4. The method of claim 3, wherein the one or more patterning layers comprises carbon.

5. The method of claim 1, wherein the one or more patterning layers comprises an extreme ultraviolet (EUV) resist material.

6. The method of claim 1, the device features of the device structure comprise silicon or a metal.

7. The method of claim 6, wherein the substrate comprises a silicon substrate and a dielectric layer that is disposed between the silicon substrate and the device structure.

8. The method of claim 6, wherein a dielectric layer is disposed within the space formed in the first direction between each of the plurality of device features.

9. The method of claim 8, further comprising:
removing the one or more patterning layers from the surface of the device structure;
etching the dielectric layer disposed in the space between each of the plurality of device features of the device structure and a portion of the substrate; and
removing the plurality of device features.

10. A method of forming a pattern in a device structure formed on a substrate, comprising:
forming one or more patterning layers over a surface of a device structure formed on the substrate, wherein:
the device structure comprises a plurality of device features having a first lateral dimension in a first direction,
the plurality of device features is spaced apart in the first direction by a first distance, and
the first direction is parallel to the surface of the device structure;
forming patterning features in the one or more patterning layers, wherein:
each of the patterning features comprises a feature opening that comprises a first critical dimension (CD), and
a first portion of a first device feature and a second portion of a second device feature of the plurality of device features are exposed within an opening in the one or more patterning layers that is defined by one or more surfaces of the feature opening;
directionally depositing a film layer on a surface of the one or more patterning layers and the patterning features, wherein:
the film layer formed within each of the feature openings comprises a first thickness and a second thickness that is formed over the one or more surfaces of the feature opening, wherein the first thickness is larger than a second thickness,
the first thickness being measured in the first direction and the second thickness being measured in a second direction that is at an angle to the first direction and is parallel to the surface of the device structure, and
one or more surfaces of the film layer exposed within each of the features openings define a film layer opening that is smaller than the first critical dimension (CD) of the feature opening,
the film layer opening is disposed over at least a portion of the first portion of the first device feature, and
the second portion of the second device feature of the plurality of device features is not exposed within the film layer opening; and
etching the at least the first portion of the first device feature of the plurality of device features that is exposed within each of the film layer openings.

11. The method of claim 10, wherein each of the plurality of device features have a second lateral dimension that is measured in the second direction, and the first critical dimension (CD) is less than the second lateral dimension.

12. The method of claim 10, wherein the film layer comprises carbon.

13. The method of claim 12, wherein the one or more patterning layers comprises carbon.

14. The method of claim 10, wherein the one or more patterning layers comprises an extreme ultraviolet (EUV) resist material.

15. The method of claim 10, the device features of the device structure comprise silicon or a metal.

16. The method of claim 15, wherein the substrate comprises a silicon substrate and a dielectric layer that is disposed between the silicon substrate and the device structure.

17. The method of claim 15, wherein a dielectric layer is disposed within the space formed in the first direction between each of the plurality of device features.

18. The method of claim 17, further comprising:
removing the one or more patterning layers from the surface of the device structure;
etching the dielectric layer disposed in the space between each of the plurality of device features of the device structure and a portion of the substrate; and
removing the plurality of device features.

19. A semiconductor device structure, comprising:
a plurality of device features having a first lateral dimension in a first direction that is parallel to a surface of the semiconductor device structure, wherein the plurality of device features is spaced apart in the first direction;
a patterning layer over the surface of the semiconductor device structure, wherein the patterning layer comprises a plurality of patterning features, each of the plurality of patterning features comprising a feature opening having a first critical dimension (CD); and
a film layer within each of the feature openings,
wherein each of the plurality of device features have a second lateral dimension that is measured in a second direction that is orthogonal to the first direction, and the first critical dimension (CD) is less than the second lateral dimension.

20. The semiconductor device structure of claim 19, wherein the film layer comprises carbon, silicon oxide, silicon nitride, silicon, or a self-assembled monolayer (SAM).
